(19) United States
(12) Patent Application Publication
(10) Pub. No.: US 2024/0096911 A1
(43) Pub. Date: Mar. 21, 2024

(54) LASER CRYSTALLIZATION APPARATUS AND LASER CRYSTALLIZATION METHOD USING THE SAME

(71) Applicant: Samsung Display Co., Ltd., Yongin-Si (KR)

(72) Inventors: DONG-MIN LEE, Yongin-si (KR); DONGGYU JIN, Yongin-si (KR)

(21) Appl. No.: 18/135,559

(22) Filed: Apr. 17, 2023

(30) Foreign Application Priority Data
Sep. 15, 2022 (KR) 10-2022-0116179

(51) Int. Cl. H01L 27/12; H01S 5/06; H01S 5/40

(52) U.S. Cl. CPC H01L 27/1274; H01S 5/0609; H01S 5/4012

(57) ABSTRACT

Provided is a laser crystallization apparatus including a beam generator generating an input laser beam, a beam converter dividing an input laser beam incident from a beam generator into a plurality of sub laser beams and disposed to have a predetermined rotation angle with respect to an optical axis parallel to a traveling direction of an input laser beam, and a beam concentrator condensing a plurality of sub laser beams and outputting an output laser beam having a beam profile having a predetermined beam width. Accordingly, a width of a stiffness area of a beam profile of an input laser beam may increase and a width of a high intensity area may decrease. Accordingly, the number of shots for the stiffness area at specific point of an amorphous silicon film may increase. Accordingly, a gradual dehydrogenation effect on an amorphous silicon film may be implemented. Accordingly, occurrence of defects in a polycrystalline silicon film formed by laser crystallization may be minimized or prevented.

### CROSS-REFERENCE TO RELATED APPLICATION

This application claims priority to Korean Patent Application No. 10-2022-0116179, filed on Sep. 15, 2022, and all the benefits accruing therefrom under 35 U.S.C. § 119, the content of which in its entirety is herein incorporated by reference.

### BACKGROUND

### 1. Field

The present disclosure generally relates to a laser crystallization apparatus and laser crystallization method using the laser crystallization apparatus. More particularly, the present disclosure relates to a laser crystallization apparatus capable of preventing an occurrence of defects in a polycrystalline silicon film and laser crystallization method using the same.

### 2. Description of the Related Art

A display device includes a thin film transistor. The thin film transistor includes an active layer. The active layer includes a polycrystalline silicon semiconductor. For example, the polycrystalline silicon semiconductor is formed by irradiating a laser to an amorphous silicon film to form a polycrystalline silicon film and then patterning the polycrystalline silicon film.

The amorphous silicon film contains hydrogen. Accordingly, after crystallization, a hydrogen explosion occurs on a surface of the polycrystalline silicon film. In this case, a defect in the polycrystalline silicon film occurs and a quality of the display device may deteriorate. Accordingly, research into minimizing the hydrogen explosion of the polycrystalline silicon film is required.

### SUMMARY

Embodiments provide a laser crystallization apparatus capable of preventing an occurrence of defects in a polycrystalline silicon film.

Embodiments provide a laser crystallization method using the laser crystallization apparatus.

A laser crystallization apparatus according to an embodiment includes a beam generator generating an input laser beam, a beam converter dividing the input laser beam incident from the beam generator into a plurality of sub laser beams and disposed to have a predetermined rotation angle with respect to an optical axis parallel to a traveling direction of the input laser beam, and a beam concentrator condensing the plurality of sub laser beams and outputting an output laser beam having a beam profile having a predetermined beam width.

In an embodiment, the rotation angle of the beam converter may be about 0.34 mrad to about 0.87 mrad.

In an embodiment, the beam profile of the output laser beam may include a first stiffness area and a second stiffness area, wherein the first stiffness area is located at a first end of the beam profile, and the second stiffness area is located at a second end of the beam profile, and a high intensity area interposed between the first stiffness area and the second stiffness area.

In an embodiment, the output laser beam may be irradiated to an amorphous silicon film at a predetermined scan pitch.

In an embodiment, the scan pitch may be constant, and the number of shots for the first stiffness area may be about 12 to about 20 at a specific point of the amorphous silicon film.

In an embodiment, the scan pitch may be constant, and a number of shots for the second stiffness area may be about 12 to about 20 at a specific point of the amorphous silicon film.

In an embodiment, the scan pitch may be constant, and a number of shots for the high intensity area may be about 20 to about 36 at a specific point of the amorphous silicon film.

In an embodiment, the scan pitch may be about 2 μm.

In an embodiment, each of a width of the first stiffness area and a width of the second stiffness area may be about 24 μm to about 40 μm.

In an embodiment, a width of the high intensity may be about 40 μm to about 72 μm.

In an embodiment, abeam width of the beam profile of the output laser beam may be about 120 μm or more.

In an embodiment, the laser crystallization apparatus may further include a beam size adjustor enlarging or reducing each of the plurality of sub laser beams.

In an embodiment, the beam size adjustor may include a telescopic lens.

A laser crystallization method according to an embodiment includes irradiating a laser beam to an amorphous silicon film using a laser crystallization apparatus, and the laser crystallization apparatus includes a beam generator generating an input laser beam, a beam converter dividing the input laser beam incident from the beam generator into a plurality of sublaser beams and disposed to have a predetermined rotation angle with respect to an optical axis parallel to a traveling direction of the input laser beam, and a concentrator condensing the plurality of sub laser beams and outputting an output laser beam having a beam profile having a predetermined beam width.

In an embodiment, the rotation angle of the beam converter may be about 0.34 mrad to about 0.87 mrad.

In an embodiment, the beam profile of the output laser beam may include a first stiffness area and a second stiffness area, wherein the first stiffness area is located at a first end of the beam profile, and the second stiffness area is located at a second end of the beam profile and a high intensity area interposed between the first stiffness area and the second stiffness area.

In an embodiment, a scan pitch at which the output laser beam is irradiated to an irradiated surface of the amorphous silicon film may be constant, and a number of shots for the first stiffness area may be about 12 to about 20 at a specific point of the amorphous silicon film.

In an embodiment, a scan pitch at which the output laser beam is irradiated to an irradiated surface of the amorphous silicon film may be constant, and a number of shots for the second stiffness area may be about 12 to about 20 at a specific point of the amorphous silicon film.

In an embodiment, a scan pitch at which the output laser beam is irradiated to an irradiated surface of the amorphous silicon film may be constant, and the number of shots for the high intensity area may be about 20 to about 36 at a specific point of the amorphous silicon film.

In an embodiment, a scan pitch at which the output laser beam is irradiated to an irradiated surface of the amorphous silicon film is constant may be about 2 μm, each of a width of the first stiffness area and a width of the second stiffness area may be about 24 μm to about 40 μm, and a width of the high intensity may be about 40 μm to about 72 μm.

Therefore, the laser crystallization apparatus according to embodiments may irradiate an output laser beam to an irradiated surface of an amorphous silicon film. The laser crystallization apparatus may include a beam converter, and the beam converter may be disposed to have a predetermined rotation angle with respect to an optical axis parallel to a traveling direction of an input laser beam. Accordingly, a width of the stiffness area of a beam profile of a laser beam may increase and a width of a high intensity area may decrease.

Accordingly, the number of shots for the stiffness area at specific point of the amorphous silicon film may increase. Accordingly, a gradual dehydrogenation effect on the amorphous silicon film may be implemented. Accordingly, after crystallization, damage due to hydrogen explosion of the polycrystalline silicon film may be minimized or prevented. Accordingly, occurrence of defects in the polycrystalline silicon film may be minimized or prevented.

It is to be understood that both the foregoing general description and the following detailed description are exemplary and explanatory and are intended to provide further explanation of the present disclosure as claimed.

### BRIEF DESCRIPTION OF THE DRAWINGS

Illustrative, non-limiting embodiments will be more clearly understood from the following detailed description taken in conjunction with the accompanying drawings.

FIG. 1 is a schematic block diagram illustrating a laser crystallization apparatus according to an embodiment.

FIG. 2 is a graph illustrating an energy distribution of an input laser beam of FIG. 1 according to an embodiment.

FIG. 3 is a schematic perspective view illustrating a beam converter included in a laser crystallization apparatus of FIG. 1 according to an embodiment.

FIG. 4 is a front view illustrating a beam converter included in a laser crystallization apparatus of FIG. 1 according to an embodiment.

FIG. 5 is a rear view illustrating a beam converter included in a laser crystallization apparatus of FIG. 1 according to an embodiment.

FIG. 6 is a graph illustrating an energy distribution of the output laser beam of FIG. 1 according to an embodiment.

FIG. 7 is schematically illustrating a method in which an output laser beam of FIG. 1 is irradiated to an object.

FIG. 8 is a block diagram schematically illustrating an arrangement state of the beam converter included in a laser crystallization apparatus of FIG. 1.

### DETAILED DESCRIPTION

The present disclosure now will be described more fully hereinafter with reference to the accompanying drawings, in which various embodiments are shown. This present disclosure may, however, be embodied in many different forms, and should not be construed as limited to the embodiments set forth herein. Rather, these embodiments are provided so that this disclosure will be thorough and complete, and will fully convey the scope of the present disclosure to those skilled in the art. Like reference numerals refer to like elements throughout.

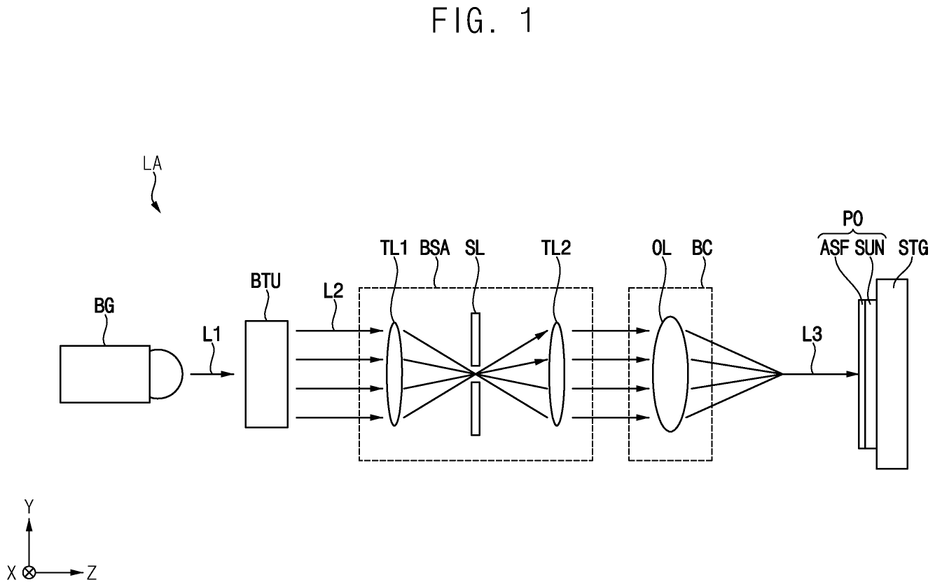

FIG. 1 is a schematic block diagram illustrating a laser crystallization apparatus according to an embodiment.

A laser beam formed by a laser crystallization apparatus LA according to an embodiment may have a long axis and a short axis. Therefore, in this specification, a direction in which light travels will be referred to as an optical axis (Z-axis), the long axis of the laser beam perpendicular to the optical axis (Z-axis) will be referred to as a X-axis, and the short axis of the laser beam perpendicular to the optical axis (Z-axis) and the long axis (X-axis) will be referred to as the Y-axis.

Referring to FIG. 1, the laser crystallization apparatus LA according to an embodiment may include a beam generator BG, a beam convertor BTU, a beam size adjustor BSA, and a beam concentrator BC. The beam generator BG, the beam convertor BTU, the beam size adjustor BSA, and the beam concentrator BC may be sequentially disposed on an optical path. The beam generator BG, the beam converter BTU, the beam size adjustor BSA, and the beam concentrator BC may be spaced apart from each other on the optical path.

The beam generator BG may generate an input laser beam L1. The beam generator BG may emit the input laser beam L1 to the beam converter BTU. The beam generator BG may continuously or discontinuously emit the input laser beam L1. The input laser beam L1 may be a single beam or multiple beams. Hereinafter, an example in which the input laser beam L1 is a single beam will be described. In an embodiment, a cross section of the input laser beam L1 may be a rectangular shape. However, the present disclosure is not necessarily limited thereto, and the cross section of the input laser beam L1 may be circular or dotted.

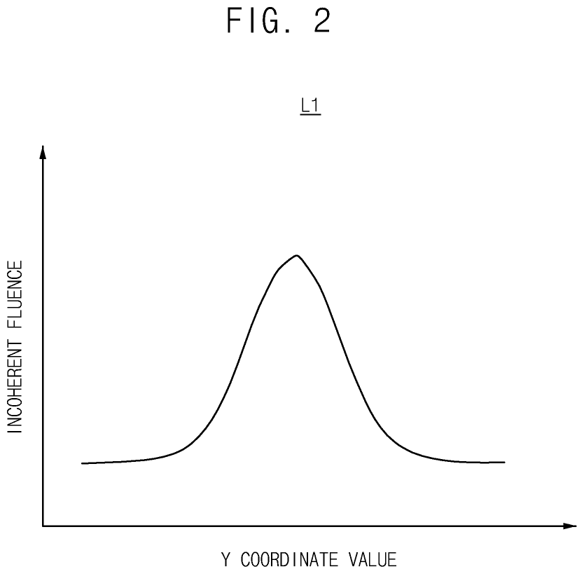

FIG. 2 is a graph illustrating an energy distribution of an input laser beam of FIG. 1 according to an embodiment. For example, FIG. 2 is a graph illustrating a Y-axis beam profile of the input laser beam L1 of FIG. 1.

Referring to FIGS. 1 and 2, in an embodiment, the input laser beam of FIG. 1 may have a Gaussian type of energy distribution.

The beam converter BTU may divide the input laser beam L1 into a plurality of sub laser beams L2. For example, the beam converter BTU may divide the input laser beam L1 into a direction corresponding to the Y-axis direction.

In an embodiment, the beam converter BTU may rotate each of the plurality of sub laser beams L2 based on the optical axis (Z-axis). In other words, the beam converter BTU may rotate a phase of the plurality of sub laser beams L2.

Although the crystallization apparatus LA is illustrated as including only one beam converter BTU in FIG. 1, the present disclosure is not necessarily limited thereto, and in another embodiment, the laser crystallization apparatus LA may include two or more beam converter BTU.

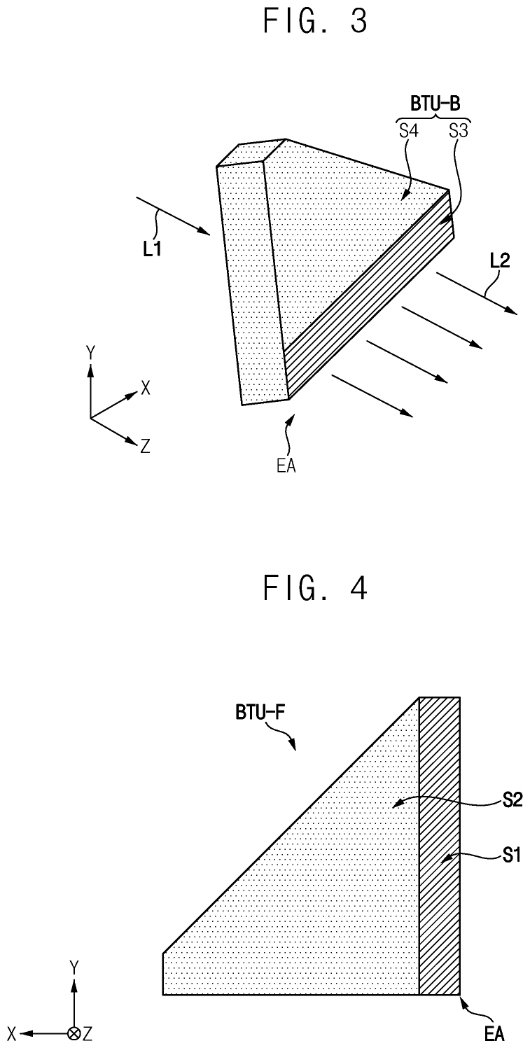

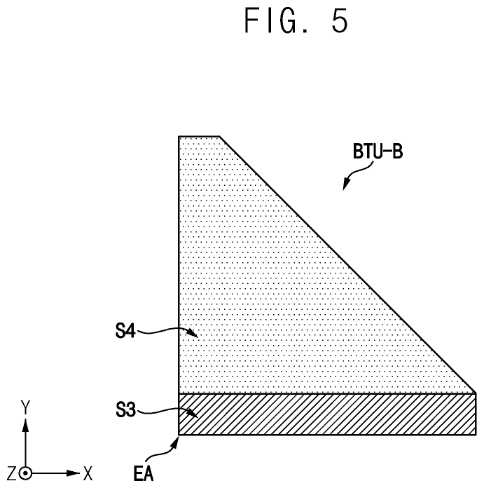

FIG. 3 is a schematic perspective view illustrating a beam converter included in a laser crystallization apparatus of FIG. 1 according to an embodiment. FIG. 4 is a front view illustrating a beam converter included in a laser crystallization apparatus of FIG. 1 according to an embodiment. FIG. 5 is a rear view illustrating a beam converter included in a laser crystallization apparatus of FIG. 1 according to an embodiment.

For example, FIG. 4 is a view illustrating the beam converter BTU of FIG. 1 viewed from between the beam generator BG, and the beam converter BTU and FIG. 5 is a view illustrating the beam converter BTU of FIG. 1 viewed from between the beam size adjustor BSA and the beam converter BTU.

Referring to FIGS. 1, 3, 4 and 5, in an embodiment, a front surface BTU-F of the beam converter BTU and the rear surface BTU-B of the beam converter BTU may be parallel to each other. In an embodiment, each of the front surface BTU-F of the beam converter BTU and the rear surface BTU-B of the beam converter BTU may have a substantially triangular shape. For example, each of the front surface BTU-F of the beam converter BTU and the rear surface BTU-B of the beam converter BTU may have two long sides extending from a common edge area EA and orthogonal to each other. However, the present disclosure is not necessarily limited thereto, and each of the front surface BTU-F of the beam converter BTU and the rear surface BTU-B of the beam converter BTU may have a rectangular or square planar shape.

In one embodiment, the front surface BTU-F of the beam converter BTU may include a first surface S1 and a second surface S2 adjacent to the first surface S1. The rear surface BTU-B of the beam converter BTU may include a third surface S3 and a fourth surface S4 adjacent to the third surface S3.

The first surface S1 may extend along one of long sides of the front surface BTU-F of the beam converter BTU. The third surface S3 may extend along one of long sides of the rear surface BTU-B of the beam converter BTU. In this case, the first surface S1 and the third surface S3 may be orthogonal to each other. In other words, the first surface S1 and the third surface S3 may overlap in the common edge area EA of the beam converter BTU.

The input laser beam L1 may be incident on the first surface S1. The plurality of sub laser beams L2 may be output from the third surface S3. In an embodiment, a predetermined antireflection material may be coated on the first surface S1 and the third surface S3.

The second surface S2 and the fourth surface S4 may have high reflectivity with respect to the laser beam. For example, a material having a high reflectivity may be coated on the second surface S2 and the fourth surface S4. Accordingly, the laser beam may be reflected at least once on the second surface S2 and the fourth surface S4. Accordingly, the input laser beam L1 incident on the first surface S1 may be reflected multiple times by the second surface S2 and the fourth surface S4. Accordingly, the input laser beam L1 incident to the first surface S1 may be divided into the plurality of sub laser beams L2 and output from the third surface S3.

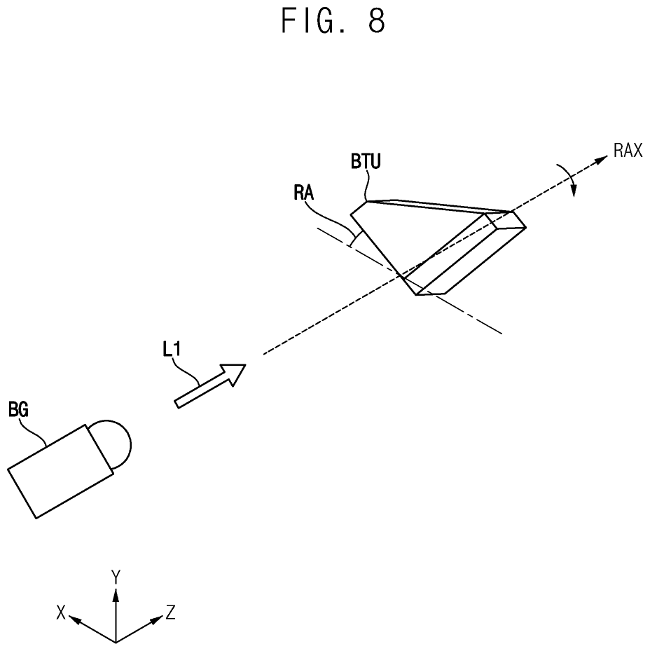

In an embodiment, the beam converter BTU may be disposed to have a predetermined rotation angle with respect to the optical axis (Z-axis). In other words, the beam converter BTU may be disposed in a state of being rotated by the rotation angle based on a rotation axis parallel to the optical axis (Z-axis). This will be described later in more detail with reference to FIG. 8.

Meanwhile, the shape and the structure of the beam converter BTU described with reference to FIGS. 1, 3, 4, and 5 are only an example and may be variously changed.

Referring back to FIG. 1, the beam size adjustor BSA may include a plurality of telescopic lenses TL1 and TL2. Each of the telescopic lenses TL1 and TL2 may be disposed to be spaced apart from each other on the optical path. Each of the telescopic lenses TL1 and TL2 may enlarge or reduce a size of the laser beam. In other words, a diameter of each of the plurality of sub laser beams L2 may be adjusted by the telescopic lenses TL1 and TL2.

For example, the first telescopic lens TL1 and the second telescopic lens TL2 may enlarge the size of the laser beam. Optionally, the first telescopic lens TL1 may enlarge the size of the laser beam, and the second telescopic lens TL2 may reduce the size of the laser beam. Optionally, the first telescopic lens TL1 may reduce the size of the laser beam, and the second telescopic lens TL2 may enlarge the size of the laser beam.

In an embodiment, each of the telescopic lenses TL1 and TL2 may be a cylindrical or spherical lens. In an embodiment, each of the telescopic lenses TL1 and TL2 may be a short axis focusing lens.

In an embodiment, the beam size adjustor BSA may further include a slit SL. The slit SL may align a progress direction of the laser beam passing through the slit SL. For example, progress directions of the plurality of sub laser beams L2 may be aligned.

The beam concentrator BC may condense the plurality of sub laser beams L2. For example, the beam concentrator BC may include a condensing lens OL. The condensing lens OL may condense the plurality of sub laser beams L2 incident on the beam concentrator BC and provide the condensed sub laser beams L2 to an object PO. In other words, the plurality of sub laser beams L2 may be imaged as an output laser beam L3 having a beam profile having a predetermined beam width on an irradiated surface of the object PO by the beam concentrator BC. In an embodiment, the condensing lens OL may be a short axis condensing lens. In this case, the plurality of sub laser beams L2 may be imaged as an output laser beam L3 having a Y-axis beam profile of a predetermined shape on the irradiated surface of the object PO.

The input laser beam L1 generated by the beam generator BG may be converted into the output laser beam L3 by the laser crystallization apparatus LA, and may be irradiated to the object PO disposed on a stage STG. In an embodiment, the object PO may be a substrate SUB and an amorphous silicon film ASF formed on the substrate SUB. Specifically, the output laser beam L3 may be irradiated to the amorphous silicon film ASF. However, a type of the object PO is not necessarily limited thereto.

In an embodiment, the amorphous silicon film ASF may be a semiconductor layer. For example, the amorphous silicon film ASF may be an a-Si layer or a compound semiconductor layer having an amorphous structure. In this case, the laser crystallization apparatus LA may perform laser crystallization on the amorphous silicon film ASF. When the output laser beam L3 is supplied to the amorphous silicon film ASF, the amorphous silicon film ASF may be crystallized to form a polycrystalline silicon film. The polycrystalline silicon film formed by performing the laser crystallization may have high charge mobility, and thus may be applied to a thin film transistor included in a display device.

The object PO may be disposed on the stage STG. In an embodiment, the stage STG may move in a predetermined direction. For example, the stage STG may move continuously or discontinuously. Accordingly, the object PO may also move along with the stage STG in a predetermined direction.

Meanwhile, a configuration and an arrangement structure of the laser crystallization apparatus LA described with reference to FIG. 1 is only an example and may be variously changed.

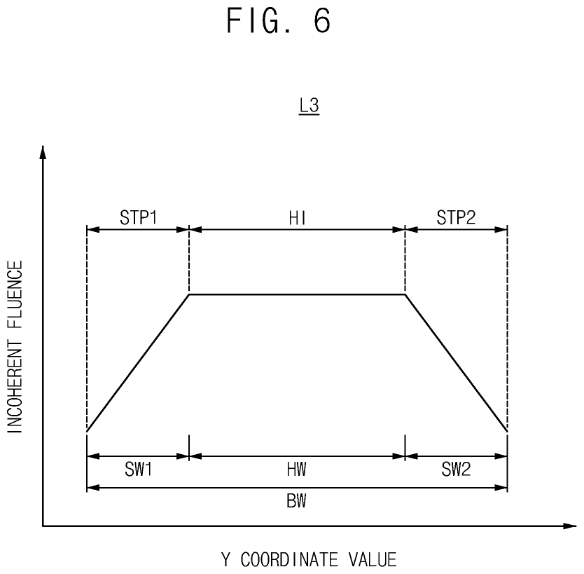

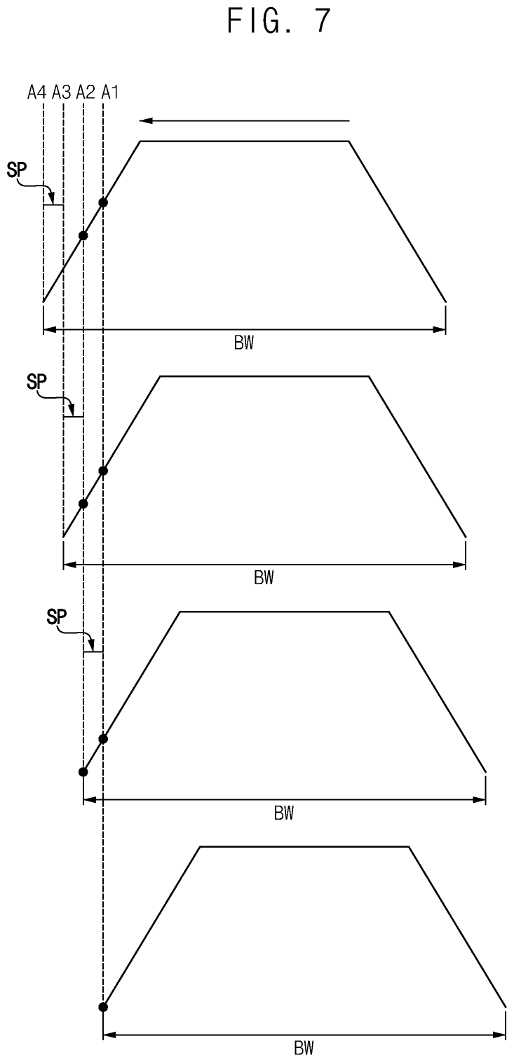

FIG. 6 is a graph illustrating an energy distribution of the output laser beam of FIG. 1 according to an embodiment. For example, FIG. 6 is a graph illustrating a Y-axis beam profile of the output laser beam L3 of FIG. 1.

Referring to FIGS. 1 and 6, the beam profile of the output laser beam L3 may be concentrated at a certain value of the Y-axis. In other words, the output laser beam L3 formed by the laser crystallization apparatus LA may have a linear beam profile having a high intensity area HI of a predetermined intensity or more.

For example, a beam profile of the output laser beam L3 may include a first stiffness area STP1, a second stiffness area STP2, and the high intensity area HI located between the first stiffness area STP1 and the second stiffness area STP2.

Each of the first stiffness area STP1 and the second stiffness area STP2 may be located at ends of the beam profile. In other words, each of the first stiffness area STP1 and the second stiffness area STP2 may be a portion where an energy intensity of the output laser beam L3 decreases toward the outside. For example, each of the first stiffness area STP1 and the second stiffness area STP2 may be an area having an intensity of about 10% to about 90% of maximum energy intensity in the beam profile of the output laser beam L3.

The high intensity area HI may be an area having an energy intensity of about 90%, preferably about 96% or more of the maximum energy intensity of the beam profile. Although FIG. 6 illustrates that the high intensity area HI is evenly distributed (that is, has the maximum energy intensity continuously within the high intensity area HI), the present disclosure is not necessarily limited thereto. In another embodiment, the high intensity area HI may be distributed at an angle with a predetermined inclination or may be distributed in a curved shape. In this case, the output laser beam L3 may have maximum energy intensity at a specific point within the high intensity area HI.

A transition area in which energy intensity varies may exist between first stiffness area STP1 and the high intensity region HI. Also, the transition area may exist between second stiffness area STP2 and the high intensity region HI. A width of the transition area may be insignificant.

In an embodiment, the first stiffness area STP1 may have a first width SW1, the second stiffness area STP2 may have a second width SW2, and the high intensity area HI may have a third width HW. A sum of the first width SW1, the second width SW2, and the third width HW may be substantially equal to a beam width BW of the beam profile of the output laser beam L3. In an embodiment, the beam width BW may be about 120 μm or more. For example, the beam width BW may be about 120 μm.

FIG. 7 is schematically illustrating a method in which an output laser beam of FIG. 1 is irradiated to an object. For example, FIG. 7 is schematically illustrating energy intensity irradiated to a specific point of the amorphous silicon film ASF when the output laser beam L3 has the beam profile of FIG. 6.

Referring to FIGS. 1, 6, and 7, in order to improve the crystallinity of the polycrystalline silicon film formed by performing the laser crystallization, in a process of irradiating the output laser beam L3 to the amorphous silicon film ASF, the output laser beam L3 having the beam profile of FIG. 6 may be repeatedly irradiated to a specific point of the amorphous silicon film ASF. Hereinafter, in this specification, the number of times the output laser beam L3 is irradiated to a specific point of the amorphous silicon film ASF will be referred to as the number of shots.

When a laser beam of high energy intensity is directly irradiated to a specific point of the amorphous silicon film ASF, defects in the polycrystalline silicon film may occur. Accordingly, crystallization may be preferentially performed by shots of areas having relatively low energy intensities, such as the first stiffness area STP1 and the second stiffness area STP2 at a specific point of the amorphous silicon film ASF and a shot of an area having high energy intensity, such as the high intensity area HI, sequentially. In other words, the output laser beam L3 may be irradiated while scanning the irradiated surface of the amorphous silicon film ASF at regular intervals. Hereinafter, in this specification, an interval at which the output laser beam L3 scans the amorphous silicon film ASF will be referred to as a scan pitch SP.

For example, in FIG. 7, first, the output laser beam L3 (in FIG. 6) may reach only a first point A1 among the first point A1 and a second point A2 of the amorphous silicon film ASF, and the output laser beam L3 may not reach the second point A2. In this case, crystallization may proceed at the first point A1 by a shot of the first stiffness area STP1, but crystallization may not proceed at the second point A2.

Thereafter, as the output laser beam L3 is scanned by the scan pitch SP, the output laser beam L3 may also reach the second point A2. Accordingly, crystallization may be repeatedly performed at the first point A1 by a shot having higher energy intensity than the previous shot. Also, crystallization may proceed at the second point A2 by the shot of the first stiffness area STP1.

Until the crystallization of the amorphous silicon film ASF is completed, the above-described process is repeated for a plurality of points including the third point A3 and the fourth point A4 of the amorphous silicon layer ASF.

As a result, the number of shots for the first stiffness area STP1 at a specific point of the amorphous silicon film ASF may correspond to a value obtained by dividing the first width SW1 of the first stiffness area STP1 by the scan pitch SP. Also, the number of shots for the second stiffness area STP2 may correspond to a value obtained by dividing the second width SW2 of the second stiffness area STP2 by the scan pitch SP. Also, the number of shots for the high intensity area HI may correspond to a value obtained by dividing the third width HW of the high intensity area HI by the scan pitch SP.

In other words, when the scan pitch SP of the output laser beam L3 having a beam profile of a predetermined beam width BW is constant, the number of shots for the first stiffness area STP1 at a specific point of the amorphous silicon layer ASF may be set by adjusting the size of the first width SW1 of the first stiffness area STP1.

In addition, when the scan pitch SP of the output laser beam L3 having a beam profile of a predetermined beam width BW is constant, the number of shots for the second stiffness area STP2 at a specific point of the amorphous silicon layer ASF may be set by adjusting the size of the second width SW2 of the second stiffness area STP1.

In addition, when the scan pitch SP of the output laser beam L3 having a beam profile of a predetermined beam width BW is constant, the number of shots for the high intensity area HI at a specific point of the amorphous silicon layer ASF may be set by adjusting the size of the third width SW3 of the high intensity area STP1.

FIG. 8 is a block diagram schematically illustrating an arrangement state of the beam converter included in a laser crystallization apparatus of FIG. 1.

Referring to FIGS. 1, 6, 7, and 8, the beam converter BTU may be disposed to have a predetermined rotation angle RA with respect to the optical axis (Z-axis). In other words, the beam converter BTU may be disposed in a state of being rotated by the rotation angle based on a rotation axis parallel to the optical axis (Z-axis).

As the beam converter BTU is disposed to have a predetermined rotation angle RA with respect to the optical axis (Z-axis), the plurality of sub laser beams L2 output from the beam converter BTU may be aligned to have a predetermined inclination for each other. In other words, the plurality of sub laser beams L2 may be aligned not parallel to each other. Accordingly, in the beam profile of the output laser beam L3 obtained by condensing the plurality of sub laser beams L2, the first width SW1 of the first stiffness area STP1 and the second width SW2 of the second stiffness area STP2 may increase. In other words, the third width HW of the high intensity area HI may decrease.

Accordingly, the number of overlapping times of each of the first stiffness area STP1 and the second stiffness area STP2 may increase with respect to a specific point of the amorphous silicon film ASF. In other words, the number of times the high intensity area HI overlaps with respect to a specific point of the amorphous silicon film ASF may decrease.

Accordingly, when the scan pitch SP of the output laser beam L3 having a beam profile of a predetermined beam width BW is constant, the number of shots for the first stiffness area STP1 at a specific point of the amorphous silicon layer ASF may increase.

In addition, when the scan pitch SP of the output laser beam L3 having a beam profile of a predetermined beam width BW is constant, the number of shots for the second stiffness area STP2 at a specific point of the amorphous silicon layer ASF may increase.

In addition, when the scan pitch SP of the output laser beam L3 having a beam profile of a predetermined beam width BW is constant, the number of shots for the high intensity area HW at a specific point of the amorphous silicon layer ASF may decrease.

Therefore, according to the laser crystallization apparatus LA according to an embodiment, the number of shots for the stiffness area STP1 and STP2 having relatively low energy intensities at a specific point of the amorphous silicon film ASF may increase and the number of shots for the high intensity area HI having relatively high energy intensity may decrease.

In an embodiment, the amorphous silicon film ASF may contain hydrogen. Accordingly, when a laser beam having high energy intensity is directly irradiated to the amorphous silicon film ASF, a hydrogen explosion may occur in the polycrystalline silicon film after crystallization. Accordingly, defects such as streaks may occur on a surface of the polycrystalline silicon film. Therefore, in order to prevent such defects, dehydrogenation treatment of the amorphous silicon film ASF may be required.

According to an embodiment, the widths of the stiffness areas STP1 and STP2 of the beam profile of the output laser beam L3 may increase. Therefore, the number of shots for the stiffness area STP1 and STP2 having relatively low energy intensities at a specific point of the amorphous silicon film ASF may increase and the number of shots for the high intensity area HI having relatively high energy intensity may decrease.

In other words, the shots of the stiffness areas STP1 and STP2 at a specific point of the amorphous silicon film ASF may function as a gradual dehydrogenation process for the amorphous silicon film ASF. Accordingly, after crystallization, damage due to hydrogen explosion of the polycrystalline silicon film may be minimized or prevented. Accordingly, occurrence of defects in the polycrystalline silicon film may be minimized or prevented.

However, if the number of shots for the high intensity area HI is excessively reduced at a specific point of the amorphous silicon film ASF, the crystallization of the amorphous silicon film ASF may not be smoothly performed. For example, a crystallization margin for the amorphous silicon film ASF may not be secured. Accordingly, it may be required to set an appropriate range for each of the number of shots for the stiffness areas STP1 and STP2 and the number of shots for the high intensity area HI, which are in a trade-off relationship with each other.

According to the laser crystallization apparatus LA, the rotation angle RA of the beam converter BTU may be about 0.34 mrad to about 0.87 mrad, preferably about 0.4 mrad to about 0.8 mrad. In other words, the beam converter BTU may be rotated by about 0.34 mrad to about 0.87 mrad, preferably by about 0.4 mrad to about 0.8 mrad based on the rotation axis RXA parallel to the optical axis (Z-axis). When the rotation angle RA of the beam converter BTU satisfies the aforementioned range, a phenomenon in which defects occur in the polycrystalline silicon film after crystallization may be minimized or prevented, and at the same time, the crystallization margin for the amorphous silicon film ASF may be secured.

In an embodiment, when the scan pitch SP of the output laser beam L3 having a beam profile of a predetermined beam width BW is constant, with respect to a specific point of the amorphous silicon film ASF, the number of shots for the first stiffness area STP1 may be about 12 to about 20, preferably about 15 to about 18.

In addition, when the scan pitch SP of the output laser beam L3 having a beam profile of a predetermined beam width BW is constant, with respect to a specific point of the amorphous silicon film ASF, The number of shots for the second stiffness area STP2 may be about 12 to about 20, preferably about 15 to about 18.

In addition, when the scan pitch SP of the output laser beam L3 having a beam profile of a predetermined beam width BW is constant, with respect to a specific point of the amorphous silicon film ASF, the number of shots for the high intensity area STP1 may be about 20 to about 36, preferably about 24 to about 30.

When the number of shots for the first stiffness area STP1, the second stiffness area STP2, and the high intensity area HI at a specific point of the amorphous silicon layer ASF satisfies the aforementioned range, a phenomenon in which defects occur in the polycrystalline silicon film after crystallization may be minimized or prevented, and at the same time, the crystallization margin for the amorphous silicon film ASF may be secured.

For example, the beam width BW of the beam profile of the output laser beam L3 may be about 120 μm, and the scan pitch SP of the output laser beam L3 may be about 2 μm.

In this case, each of the first width SW1 of the first stiffness area STP1 and the second width SW2 of the second stiffness area STP2 may be about 24 μm to about 40 μm. Also, the third width HW of the high intensity area HI may be about 40 μm to about 72 μm. Accordingly, at a specific point of the amorphous silicon film ASF, the number of shots for the first stiffness area STP1 may be about 12 to about 20, and the number of shots for the second stiffness area STP2 may be about 12 to about 20, and the number of shots for the high intensity area HI may be about 20 to about 36. Accordingly, a phenomenon in which defects occur in the polycrystalline silicon film after crystallization may be minimized or prevented, and at the same time, the crystallization margin for the amorphous silicon film ASF may be secured.

According to the laser crystallization apparatus LA and the laser crystallization method using the laser crystallization apparatus, the laser beam may be irradiated to the irradiated surface of the amorphous silicon film. In this case, the laser crystallization apparatus may include the beam converter, and the beam converter may be disposed to have a predetermined rotation angle with respect to the optical axis parallel to a traveling direction of the input laser beam. Accordingly, the width of the stiffness area of the beam profile of the laser beam may increase and the width of the high intensity area may decrease.

Accordingly, the number of shots for the stiffness area at specific point of the amorphous silicon film may increase. Accordingly, a gradual dehydrogenation effect on the amorphous silicon film ASF may be implemented. Accordingly, after crystallization, damage due to hydrogen explosion of the polycrystalline silicon film may be minimized or prevented. Accordingly, occurrence of defects in the polycrystalline silicon film may be minimized or prevented.

The present disclosure should not be construed as being limited to the embodiments set forth herein. Rather, these embodiments are provided so that this disclosure will be thorough and complete and will fully convey the concept of the present disclosure to those skilled in the art.

While the present disclosure has been particularly shown and described with reference to embodiments thereof, it will be understood by those of ordinary skill in the art that various changes in form and details may be made therein without departing from the spirit or scope of the present disclosure as defined by the following claims.

What is claimed is:

1. A laser crystallization apparatus comprising:
a beam generator generating an input laser beam;
a beam converter dividing the input laser beam incident from the beam generator into a plurality of sub laser beams and disposed to have a predetermined rotation angle with respect to an optical axis parallel to a traveling direction of the input laser beam; and
a beam concentrator condensing the plurality of sub laser beams and outputting an output laser beam having a beam profile having a predetermined beam width.

2. The laser crystallization apparatus of claim 1, wherein the rotation angle of the beam converter is about 0.34 mrad to about 0.87 mrad.

3. The laser crystallization apparatus of claim 1, wherein the beam profile of the output laser beam includes:
a first stiffness area and a second stiffness area, wherein the first stiffness area is located at a first end of the beam profile, and the second stiffness area is located at a second end of the beam profile; and
a high intensity area interposed between the first stiffness area and the second stiffness area.

4. The laser crystallization apparatus of claim 3, wherein the output laser beam is irradiated to an amorphous silicon film at a predetermined scan pitch.

5. The laser crystallization apparatus of claim 4, wherein the scan pitch is constant, and
wherein a number of shots for the first stiffness area is about 12 to about 20 at a specific point of the amorphous silicon film.

6. The laser crystallization apparatus of claim 4, wherein the scan pitch is constant, and
wherein a number of shots for the second stiffness area is about 12 to about 20 at a specific point of the amorphous silicon film.

7. The laser crystallization apparatus of claim 4, wherein the scan pitch is constant, and
wherein a number of shots for the high intensity area is about 20 to about 36 at a specific point of the amorphous silicon film.

8. The laser crystallization apparatus of claim 4, wherein the scan pitch is 2 μm.

9. The laser crystallization apparatus of claim 8, wherein each of a width of the first stiffness area and a width of the second stiffness area is about 24 μm to about 40 μm.

10. The laser crystallization apparatus of claim 8, wherein a width of the high intensity is about 40 μm to about 72 μm.

11. The laser crystallization apparatus of claim 1, wherein a beam width of the beam profile of the output laser beam is about 120 μm or more.

12. The laser crystallization apparatus of claim 1, further comprising:
a beam size adjustor enlarging or reducing each of the plurality of sub laser beams.

13. The laser crystallization apparatus of claim 10, wherein the beam size adjustor includes a telescopic lens.

14. A laser crystallization method comprising:
irradiating a laser beam to an amorphous silicon film using a laser crystallization apparatus,
wherein the laser crystallization apparatus includes:
a beam generator generating an input laser beam;
a beam converter dividing the input laser beam incident from the beam generator into a plurality of sub laser beams and disposed to have a predetermined rotation angle with respect to an optical axis parallel to a traveling direction of the input laser beam; and
a concentrator condensing the plurality of sub laser beams and outputting an output laser beam having a beam profile having a predetermined beam width.

15. The laser crystallization method of claim 14, wherein the rotation angle of the beam converter is about 0.34 mrad to about 0.87 mrad.

16. The laser crystallization method of claim 15, wherein the beam profile of the output laser beam includes:
a first stiffness area and a second stiffness area, wherein the first stiffness area is located at a first end of the beam profile, and the second stiffness area is located at a second end of the beam profile; and
a high intensity area interposed between the first stiffness area and the second stiffness area.

17. The laser crystallization method of claim 16, wherein a scan pitch at which the output laser beam is irradiated to an irradiated surface of the amorphous silicon film is constant, and
wherein a number of shots for the first stiffness area is about 12 to about 20 for a specific point of the amorphous silicon film.

18. The laser crystallization method of claim 16, wherein a scan pitch at which the output laser beam is irradiated to an irradiated surface of the amorphous silicon film is constant, and
wherein a number of shots for the second stiffness area is about 12 to about 20 at a specific point of the amorphous silicon film.

19. The laser crystallization method of claim 16, wherein a scan pitch at which the output laser beam is irradiated to an irradiated surface of the amorphous silicon film is constant, and
wherein a number of shots for the high intensity area is about 20 to about 36 for a specific point of the amorphous silicon film.

20. The laser crystallization method of claim 16, wherein a scan pitch at which the output laser beam is irradiated to an irradiated surface of the amorphous silicon film is about 2 μm,
wherein each of a width of the first stiffness area and a width of the second stiffness area is about 24 μm to about 40 μm, and
wherein a width of the high intensity is about 40 μm to about 72 μm.
